(19) United States
(12) Patent Application Publication
(10) Pub. No.: US 2026/0123426 A1
(43) Pub. Date: Apr. 30, 2026

(54) ELECTRONIC DEVICE

(71) Applicant: Advanced Semiconductor Engineering, Inc., Kaohsiung (TW)

(72) Inventors: Yu Shan HUANG, Kaohsiung (TW); Chingyao HSU, Kaohsiung (TW); Jenchun CHEN, Kaohsiung (TW)

(73) Assignee: Advanced Semiconductor Engineering, Inc., Kaohsiung (TW)

(21) Appl. No.: 18/934,164

(22) Filed: Oct. 31, 2024

(51) Int. Cl. H01L 23/42; H01L 23/00; H01L 23/31; H01L 23/538; H01L 25/065

(52) U.S. Cl. CPC H10W 40/70; H10W 74/114; H10W 90/00; H10W 70/60; H10W 70/611; H10W 72/884; H10W 90/734; H10W 90/755

(57) ABSTRACT

The present disclosure provides an electronic device. The electronic device includes a die, a thermal dissipating structure, and an encapsulant. The thermal dissipating structure is disposed over the die. The thermal dissipating structure has a thickness tapered along a direction far from the die. The encapsulant encapsulates the die and the thermal dissipating structure.

### BACKGROUND

### 1. Technical Field

The present disclosure relates to an electronic device.

### 2. Description of the Related Art

In a comparative method of packaging a power die (such as a power metal-oxide-semiconductor field-effect transistor (MOSFET) or an insulated gate bipolar transistor (IGBT)), two or more heat-dissipating structures are mounted on opposite sides of an electronic device. However, increasing the dimensions (e.g., thickness) can adversely impact the miniaturization of the electronic device.

### SUMMARY

In some arrangements, an electronic device includes a die, a thermal dissipating structure, and an encapsulant. The thermal dissipating structure is disposed over the die. The thermal dissipating structure has a thickness tapered along a direction far from the die. The encapsulant encapsulates the die and the thermal dissipating structure.

In some arrangements, an electronic device includes a substrate and a thermal dissipating structure. The substrate supports a plurality of dies. The thermal dissipating structure is disposed over the substrate. The thermal dissipating structure includes a first base portion, a second base portion, and a connection portion connecting the first base portion and the second base portion. The connection portion exceeds toward a first side and a second side of the die.

In some arrangements, an electronic device includes a substrate and a thermal dissipating structure. The thermal dissipating structure is disposed over the substrate. The thermal dissipating structure includes a first base portion, a second base portion, and a connection portion connecting the first base portion and the second base portion. An upper surface of the connection portion continuously extends from a first side to a second side of the thermal dissipating structure and overhangs the first base portion and the second base portion.

### BRIEF DESCRIPTION OF THE DRAWINGS

Aspects of some arrangements of the present disclosure are best understood from the following detailed description when read with the accompanying figures. It is noted that various structures may not be drawn to scale, and dimensions of the various structures may be arbitrarily increased or reduced for clarity of discussion.

FIG. 1A illustrates a top view of an electronic device in accordance with some arrangements of the present disclosure.

FIG. 1B illustrates a cross-sectional view along line A-A′ of the electronic device as shown in FIG. 1A in accordance with some arrangements of the present disclosure.

FIG. 2 illustrates a cross-sectional view of an electronic device in accordance with some arrangements of the present disclosure.

FIG. 3 illustrates a cross-sectional view of an electronic device in accordance with some arrangements of the present disclosure.

FIG. 4 illustrates a cross-sectional view of an electronic device in accordance with some arrangements of the present disclosure.

FIG. 5A illustrates a top view of an electronic device in accordance with some arrangements of the present disclosure.

FIG. 5B illustrates a side view of the electronic device as shown in FIG. 5A in accordance with some arrangements of the present disclosure.

FIG. 6 illustrates a side view of an electronic device in accordance with some arrangements of the present disclosure.

FIG. 7 illustrates a side view of an electronic device in accordance with some arrangements of the present disclosure.

FIG. 8 illustrates a side view of an electronic device in accordance with some arrangements of the present disclosure.

FIG. 9 illustrates a cross-sectional view of an electronic device in accordance with some arrangements of the present disclosure.

### DETAILED DESCRIPTION

The following disclosure provides for many different arrangements, or examples, for implementing different features of the provided subject matter. Specific examples of components and arrangements are described as follows to explain certain aspects of the present disclosure. These are, of course, merely examples and are not intended to be limiting. For example, the formation of a first feature over or on a second feature in the description that follows may include arrangements in which the first and second features are formed or disposed in direct contact, and may also include arrangements in which additional features may be formed or disposed between the first and second features, such that the first and second features may not be in direct contact. In addition, the present disclosure may repeat reference numerals and/or letters in the various examples. This repetition is for the purpose of simplicity and clarity and does not in itself dictate a relationship between the various arrangements and/or configurations discussed.

Spatial descriptions, such as “above,” “below,” “up,” “left,” “right,” “down,” “top,” “bottom,” “vertical,” “horizontal,” “side,” “higher,” “lower,” “upper,” “over,” “under,” and so forth, are indicated with respect to the orientation shown in the figures unless otherwise specified. It should be understood that the spatial descriptions used herein are for purposes of illustration only, and that practical implementations of the structures described herein can be spatially arranged in any orientation or manner, provided that the merits of arrangements of this disclosure are not deviated from by such arrangement.

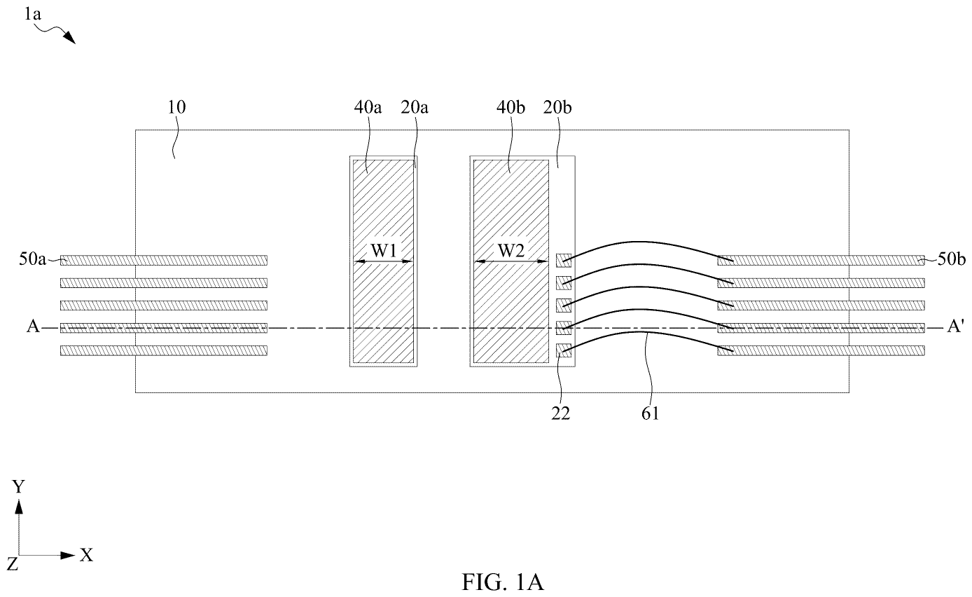

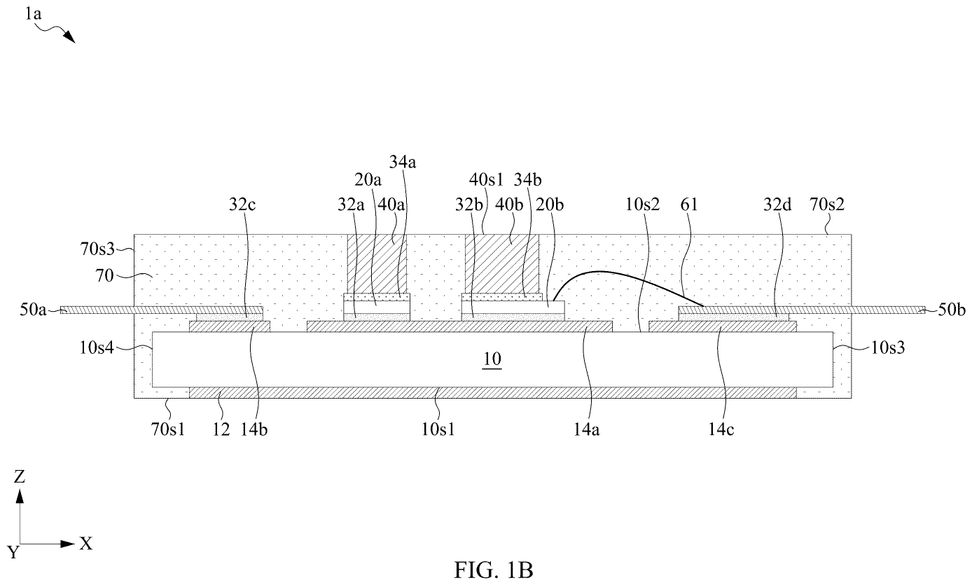

FIG. 1A illustrates a top view of an electronic device 1a in accordance with some arrangements of the present disclosure. FIG. 1B illustrates a cross-sectional view along line A-A′ of the electronic device 1a as shown in FIG. 1A in accordance with some arrangements of the present disclosure.

Referring to FIG. 1A, the electronic device 1a may include a substrate 10, electronic components 20a and 20b, thermal dissipating structures 40a and 40b, conductive elements 50a and 50b, and conductive wires 61. It should be noted that some of the features are omitted from the top view for brevity. In some embodiments, the substrate 10 may be configured to support the electronic components 20a and 20b. In some embodiments, the thermal dissipating structure 40a may be disposed on or over the electronic component 20a. In some embodiments, the thermal dissipating structure 40b may be disposed on or over the electronic component 20b. In some embodiments, the electronic component 20b may include pads 22 exposed from an upper surface of the electronic component 20b. The pads 22 of the electronic component 20b may be electrically connected to the conductive elements 50b by conductive wires 61.

Referring to FIG. 1B, in some embodiments, the substrate 10 may include a ceramic base (or other suitable materials) and a circuit pattern formed therein. In some embodiments, the substrate 10 may include a direct bonded copper (DBC) substrate obtained by sintering and bonding metal plates 12, 14a, 14b, and 14c on both sides of the ceramic base using heat and pressure. The substrate 10 may have the advantage of excellent heat dissipation and heat conduction characteristics. The substrate 10 may have a surface 10s1 (or a lower surface) and a surface 10s2 (or an upper surface) opposite to the surface 10s1. The substrate 10 may have a surface 10s3 (or a lateral surface or side) and a surface 10s4 (or a lateral surface or side) opposite to the surface 10s3. The surfaces 10s3 and 10s4 may extend between the surface 10s1 and surface 10s2.

The metal plate 12 may be disposed on or under the surface 10s1 of the substrate 10. The metal plates 14a, 14b, and 14c may be disposed on or over the surface 10s2 of the substrate 10. The metal plates 12, 14a, 14b, and 14c may include copper, aluminum, gold, silver, titanium, or other suitable materials.

The electronic component 20a may be disposed on or over the surface 10s2 of the substrate 10. The electronic component 20a may be electrically connected to the metal plate 14a. In some embodiments, the electronic component 20a may include a die (e.g., a power die) or a chip including a semiconductor substrate, one or more integrated circuit devices and/or one or more overlying interconnection structures therein. The integrated circuit devices may include active devices such as transistors and diodes. The integrated circuit devices may include passive devices such resistors, capacitors, inductors, or a combination thereof. In some embodiments, the electronic component 20a includes a power metal-oxide-semiconductor field-effect transistor (MOSFET) device, an insulated gate bipolar transistor (IGBT) device, and/or a junction gate field-effect transistor (JFET) device.

The electronic component 20b may be disposed on or over the surface 10s2 of the substrate 10. The electronic component 20b may be electrically connected to the metal plate 14a. In some embodiments, the electronic component 20b may include a die (e.g., a power die) or a chip including a semiconductor substrate, one or more integrated circuit devices and/or one or more overlying interconnection structures therein. The integrated circuit devices may include active devices such as transistors and diodes. The integrated circuit devices may include passive devices such resistors, capacitors, inductors, or a combination thereof. In some embodiments, the electronic component 20b includes a power MOSFET device, an IGBT device, and/or a JFET device.

In some embodiments, the electronic component 20a may include a diode, and the electronic component 20b may include an IGBT device. In some embodiments, the electronic components 20a and 20b may function as a power module. In some embodiments, the electronic components 20a and 20b may be collectively configured to function as a converter, converting an input alternating current (AC) power to direct current (DC) power. In some embodiments, the electronic component 20b may be coupled to the electronic component 20a.

The electronic device 1a may include electrical connectors 32a, 32b, 32c, and 32d over the substrate 10. The electrical connector 32a may be disposed between and electrically connect the electronic component 20a and the metal plate 14a. The electrical connector 32b may be disposed between and electrically connect the electronic component 20b and the metal plate 14a. The electrical connector 32c may be disposed between and electrically connect the conductive elements 50a and the metal plate 14b. The electrical connector 32d may be disposed between and electrically connect the conductive elements 50b and the metal plate 14d. The electrical connectors 32a, 32b, 32c, and 32d may include a conductive material. In some embodiments, the electrical connectors 32a, 32b, 32c, and 32d may include a reflowable material, such as a solder material, which may include alloys of gold and tin solder or alloys of silver and tin solder, or other suitable materials.

In some embodiments, the electronic device 1a may include connection layers 34a and 34b. The connection layer 34a may be disposed on or over the electronic component 20a. The connection layer 34b may be disposed on or over the electronic component 20b. In some embodiments, the connection layer 34a may be disposed between and configured to transmit heat between the thermal dissipating structure 40a and the electronic component 20a. In some embodiments, the connection layer 34b may be disposed between and configured to transmit heat between the thermal dissipating structure 40b and the electronic component 20b. In some embodiments, the connection layers 34a and 34b may include electrically insulative material, such as thermal insulative material (TIM), or other suitable materials.

In some embodiments, the thermal dissipating structure 40a may be disposed on or over the electronic component 20a. In some embodiments, the thermal dissipating structure 40b may be disposed on or over the electronic component 20b. In some embodiments, the thermal dissipating structures 40a and 40b may have a non-zero distance therebetween. The thermal dissipating structure 40a may be spaced apart from the thermal dissipating structure 40b. As shown in FIG. 1A, a width W1 of the thermal dissipating structure 40a may be different from a width W2 of the thermal dissipating structure 40b along the X direction.

In some embodiments, the thermal dissipating structure 40a may be thermally coupled to the electronic component 20a through the connection layer 34a. In some embodiments, the thermal dissipating structure 40b may be thermally coupled to the electronic component 20b through the connection layer 34b. In some embodiments, the thermal dissipating structures 40a and 40b may be configured to transmit the heat of the electronic device 1a to the surroundings. In some embodiments, the thermal dissipating structures 40a and 40b do not have electrically transmissive functions. In some embodiments, the thermal dissipating structures 40a and 40b may include thermally conductive materials, such as metal, metal alloy, ceramic, or other suitable materials. As shown in 1A, a portion of the upper surface of the electronic component 20b may be exposed by the thermal dissipating structure 40b. In some embodiments, the upper surface of the electronic component 20a may be fully covered by the thermal dissipating structure 40a. In other embodiments, a portion of the upper surface of the electronic component 20a may be exposed by the thermal dissipating structure 40a.

The conductive elements 50a may be disposed on or over the surface 10s2 of the substrate 10. The conductive elements 50b may be disposed on or over the surface 10s2 of the substrate 10. The conductive elements 50b may be electrically coupled to the electronic component 20b through the conductive wires 61. In some embodiments, the conductive elements 50a and 50b may be a part of a leadframe or other suitable conductive features. In some embodiments, the conductive elements 50a and 50b may include leads, or other suitable elements. In some embodiments, the conductive elements 50a may provide an external connection between the electronic device 1a and other components (not shown).

In some embodiments, the conductive wires 61 (or conductive elements or bendable conductive elements) may be configured to electrically connect the electronic component 20b and the conductive elements 50b. In some embodiments, the conductive wires 61 may include a bonding wire which is bendable. The conductive wires 61 may include copper, nickel, gold, silver, or other suitable materials.

In some embodiments, the electronic device 1a may further include an encapsulant 70. In some embodiments, the encapsulant 70 may be disposed on or over the surface 10s2 of the substrate 10. In some embodiments, the encapsulant 70 may cover the surface 10s3 of the substrate 10. In some embodiments, the encapsulant 70 may cover the surface 10s4 of the substrate 10. In some embodiments, the encapsulant 70 may encapsulate the electronic components 20a and 20b. In some embodiments, the encapsulant 70 may encapsulate the thermal dissipating structures 40a and 40b. In some embodiments, the encapsulant 70 may encapsulate a portion of the conductive elements 50a and 50b. In some embodiments, the encapsulant 70 may encapsulate the conductive wires 61. In some embodiments, a surface 40s1 (or an upper surface) of the thermal dissipating structure 40a (or thermal dissipating structure 40b) may be exposed by the encapsulant 70. The encapsulant 70 may have a surface 70s1 (or a lower surface) and a surface 70s2 (or an upper surface) opposite to the surface 70s1. The surface 70s1 may be substantially aligned with the surface 40s1. The encapsulant 70 may include a novolac-based resin, an epoxy-based resin, a silicone-based resin, or another suitable material. The encapsulant 70 may be applied using any of a number of molding techniques, such as compression molding, injection molding, or transfer molding.

In a comparative example, in order to transmit heat more effectively, two DBC substrates are disposed on two opposite sides of a power module, which increases the overall thickness of the device. In this embodiment, DBC on the upper side (e.g., the side abutting the surface 70s2 of the encapsulant 70) of the electronic device 1a may be omitted. The thermal dissipating structures 40a and 40b may be used to transmit heat. Further, the upper surfaces of the thermal dissipating structures 40a and 40b may be intentionally exposed to air or left exposed by the encapsulant 70 in order to improve their thermal transmissivity. In addition, as the thermal dissipating structures 40a and 40b do not serve any electrical connectivity functions, their upper surface area can be expanded to cover multiple power modules, thereby further enhancing their thermal transmissivity.

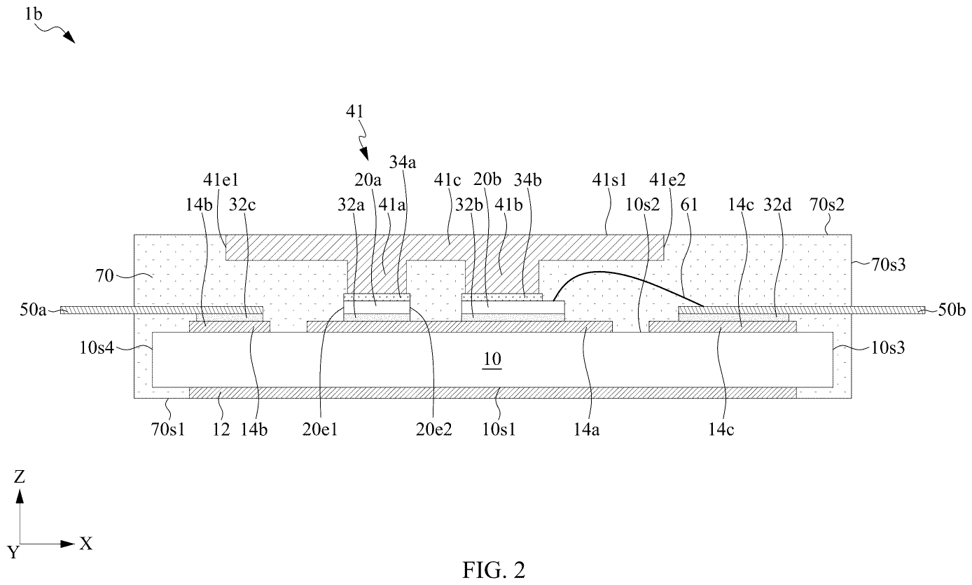

FIG. 2 illustrates a cross-sectional view of an electronic device 1b in accordance with some arrangements of the present disclosure. The electronic device 1b is similar to the electronic device 1a in FIG. 1B except for the differences described as follows.

In some embodiments, the electronic device 1b may include a thermal dissipating structure 41 over the substrate 10. In some embodiments, the thermal dissipating structure 41 may include a base portion 41a connected to the electronic component 20a, a base portion 41b connected to the electronic component 20b, and a connection portion 41c connecting the base portions 41a and 41b.

The base portion 41a may extend vertically and have a substantially uniform width in a cross-sectional view. The base portion 41b may extend vertically and have a substantially uniform width in a cross-sectional view. In some embodiments, the connection portion 41c may have a substantially uniform thickness along the Z direction. In some embodiments, the connection portion 41c may have a surface 41s1 (or an upper surface) exposed by the encapsulant 70. In some embodiments, the surface 41s1 may extend continuously or span continuously. For example, the surface 41s1 may have a rectangular profile, a square profile, or other suitable profiles in a top view. The surface 41s1 may be free of an indentation(s) in a top view so that the surface 41s1 may have a greater surface area to enhance the thermal transmittance. In a cross-sectional view, the surface 41s1 continuously extends from a side 41e1 (or the first furthest side) to a side 41e2 (or the second furthest side). In a cross-sectional view, the connection portion 41c overhangs the base portions 41a and 41b.

In some embodiments, the connection portion 41c and the base portion 41b (or base portion 41a) may be configured to define a space for accommodating other elements, such as the conductive wires 61 or other components. In some embodiments, the connection portion 41c may vertically overlap the conductive elements 50a. In some embodiments, the connection portion 41c may vertically overlap the conductive elements 50b. In some embodiments, the connection portion 41c may vertically overlap the conductive wires 61. In some embodiments, the connection portion 41c may extend beyond the lateral surface (or edge) of the electronic component 20a. In some embodiments, the connection portion 41c may extend beyond the lateral surface (or edge) of the electronic component 20b. For example, the connection portion 41c may extend beyond sides 20e1 and 20e2 (or edges) of the electronic component 20a in a cross-sectional view.

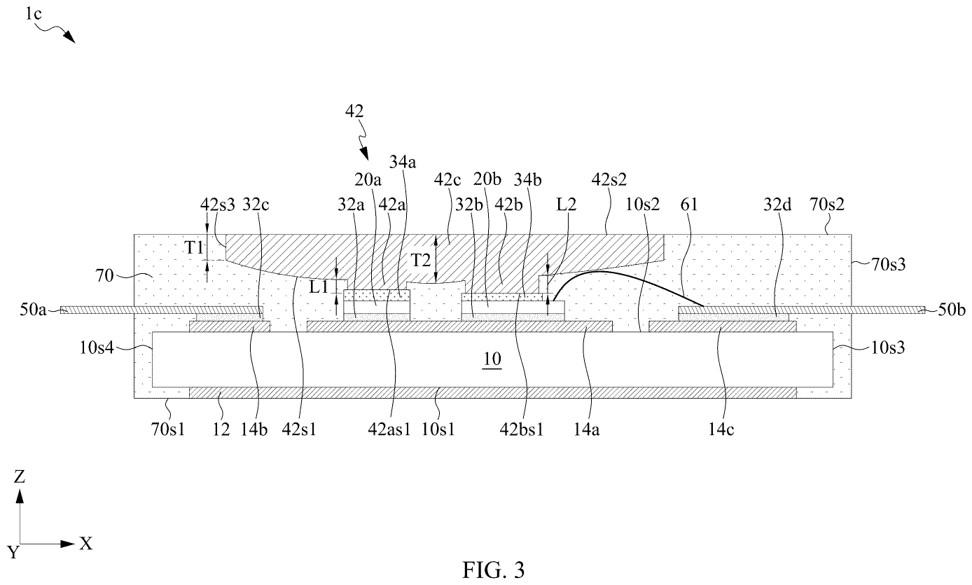

FIG. 3 illustrates a cross-sectional view of an electronic device 1c in accordance with some arrangements of the present disclosure. The electronic device 1c is similar to the electronic device 1a in FIG. 1B except for the differences described as follows.

In some embodiments, the electronic device 1c may include a thermal dissipating structure 42 over the substrate 10. In some embodiments, thermal dissipating structure 42 may include a base portion 42a connected to the electronic component 20a, a base portion 42b connected to the electronic component 20b, and a connection portion 42c connecting the base portions 42a and 42b. In some embodiments, the base portions 42a and 42b may have different lengths along the Z direction. For example, the base portion 42a may have a length L1, and the base portion 42b may have a length L2 greater than the length L1. In some embodiments, a surface 42as1 (e.g., a lower surface) of the base portion 42a may be at an elevation, with respect to the surface 10s2 of the substrate 10, higher than an elevation of a surface 42bs1 (e.g., a lower surface) of the base portion 42b.

The connection portion 42c may have a surface 42s1 (or a lower surface), a surface 42s2 (or an upper surface), and a surface 42s3 (or a lateral surface or edge) extending between the surfaces 42s1 and 42s2. In some embodiments, the connection portion 42c may have a nonuniform thickness, which may be defined as a distance between the surfaces 42s1 and 42s2. In some embodiments, the thickness of the connection portion 42c become smaller along a direction far away from the electronic component 20a (or electronic component 20b). In some embodiments, the thickness of the connection portion 42c become smaller toward the side (e.g., surface 10s3 or 10s4) of the substrate 10. In some embodiments, the connection portion 42c may have a smaller thickness abutting the edge of the connection portion 42c and a greater thickness far from the edge of the connection portion 42c. For example, the connection portion 42c may have a thickness T1 abutting the surface 42s3 and a thickness T2 between the base portions 42a and 42b. In some embodiments, the thickness T1 may be less than the thickness T2. Therefore, the thermal dissipating structure 42 may define more additional space for accommodating other elements (e.g., the conductive wires 61) to prevent the thermal dissipating structure 42 from being electrically connected with other elements.

In some embodiments, the surface 42s1 may have a curved surface. Therefore, the thermal dissipating structure 42 may have a greater surface area, enhancing the thermal transmittance.

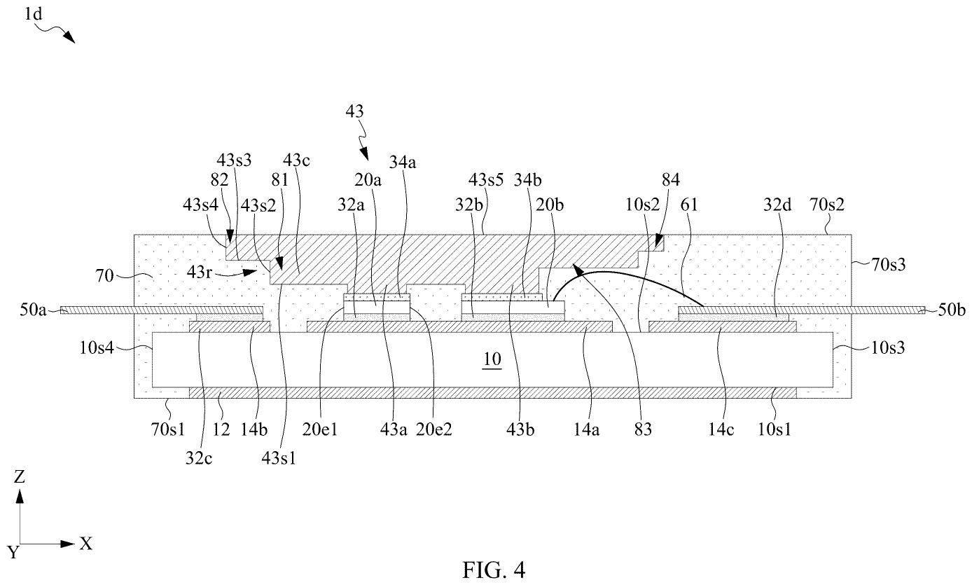

FIG. 4 illustrates a cross-sectional view of an electronic device 1d in accordance with some arrangements of the present disclosure. The electronic device 1d is similar to the electronic device 1a in FIG. 1B except for the differences described as follows.

In some embodiments, the electronic device 1c may include a thermal dissipating structure 43 over the substrate 10. In some embodiments, the thermal dissipating structure 43 may include a base portion 43a connected to the electronic component 20a, a base portion 43b connected to the electronic component 20b, and a connection portion 43c connecting the base portions 43a and 43b. In some embodiments, the connection portion 43c may have one or more step structures. The connection portion 43c may have a surface 43s1, a surface 43s2 connected to and substantially orthogonal to the surface 43s1, a surface 43s3 connected to and substantially orthogonal to the surface 43s2, a surface 43s4 connected and substantially orthogonal to the surface 43s3, and a surface 43s5 exposed by the encapsulant 70. The surfaces 43s1 and 43s3 may be collectively referred to as the bottom surface of the connection portion 43c.

The surfaces 43s1 and 43s2 may define a step structure 81. The surfaces 43s3 and 43s4 may define a step structure 82. The step structures 81 and 82 may define a recess 43r. In some embodiments, the step structures 81 and 82 may be located at the same side (e.g., the side 20e1) of the electronic component 20a. The step structure 82 may be at an elevation, with respect to the surface 10s2 of the substrate 10, different from that of the step structure 81. Similarly, the connection portion 43c may define a step structure 83 and a step structure 84 on another side (e.g., the side 20e2) of the electronic component 20a. In some embodiments, the bottom of the step structure 83 may be located at an elevation different from the bottom (e.g., the surface 43s1) of the step structure 81. The step structure 84 may be located at an elevation different from that of the step structure 83.

In some embodiments, the step structures 81, 82, 83, and 84 may allow the thermal dissipating structure 43 to have a greater surface area, thereby enhancing the thermal transmittance. In some embodiments, the step structures may be configured to define a space for accommodating other elements. For example, the step structures 83 and 84 may define a space for accommodating the conductive wires 61. In this embodiment, the bottom surface of the connection portion 43c may have a topography (e.g., step structures or recesses) designed to accommodate other components.

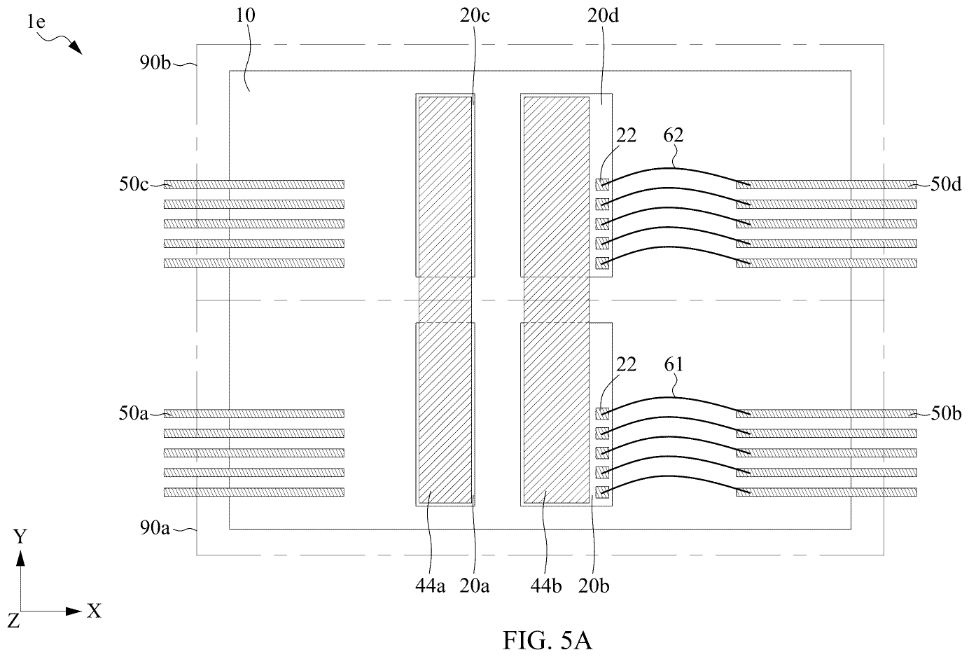

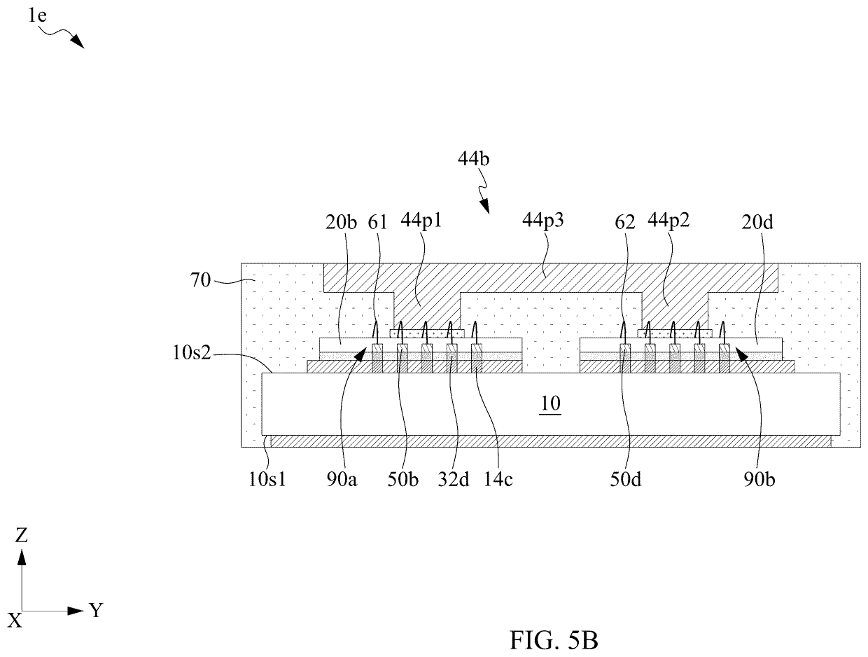

FIG. 5A illustrates a top view of an electronic device 1e in accordance with some arrangements of the present disclosure. FIG. 5B illustrates a side view of FIG. 5A in accordance with some arrangements of the present disclosure. It should be noted that some of the features are omitted for brevity. In some embodiments, the electronic device 1e may include two or more power modules.

In some embodiments, the electronic device 1e may include power modules 90a and 90b. The power module 90a may include a structure similar to that shown in FIGS. 1A and 1B. The power module 90b may include electronic components 20c and 20d, conductive elements 50c and 50d, and conductive wires 62, which may be similar to electronic components 20a and 20b, conductive elements 50a and 50b, and conductive wires 61, respectively. In some embodiments, the power module 90a may be electrically isolated from the power module 90b. In some embodiments, the power module 90a may be electrically coupled to the power module 90b by the substrate 10. In some embodiments, the electronic components 20c and 20d may function as a power module. In some embodiments, the electronic components 20c and 20d may be collectively configured to function as a converter, converting an AC power to DC power. In some embodiments, the electronic component 20d may be coupled to the electronic component 20c.

In some embodiments, the electronic device 1e may include thermal dissipating structures 44a and 44b. In some embodiments, the thermal dissipating structure 44a may be thermally coupled to the electronic components 20a and 20c. In some embodiments, the thermal dissipating structure 44a may extend from electronic component 20a to the electronic component 20c. The thermal dissipating structure 44a may be electrically isolated from the electronic component 20a by an insulative material (e.g., TIM). The thermal dissipating structure 44a may be electrically isolated from the electronic component 20c by an insulative material (e.g., TIM). In some embodiments, the thermal dissipating structure 44b may be thermally coupled to the electronic components 20b and 20d. In some embodiments, the thermal dissipating structure 44b may extend from electronic component 20b to the electronic component 20d. The thermal dissipating structure 44b may be electrically isolated from the electronic component 20b by an insulative material (e.g., TIM). The thermal dissipating structure 44b may be electrically isolated from the electronic component 20d (e.g., TIM).

In some embodiments, the thermal dissipating structure 44a may extend between power modules 90a and 90b. In some embodiments, the thermal dissipating structure 44b may extend between power modules 90a and 90b. Since the thermal dissipating structures 44a and 44b do not have electrically connective functions, the power module 90a cannot be electrically coupled to the power module 90b by the thermal dissipating structures 44a and 44b. In some embodiments, the thermal dissipating structure 44b may have a portion 44p1 (or a base portion) over the electronic component 20b of the power module 90a and a portion 44p2 (or a base portion) over the electronic component 20d of the power module 90b. The thermal dissipating structure 44b may have a portion 44p3 (or a connection portion) connecting the portions 44p1 and 44p2. In some embodiments, the portion 44p3 may extend and be coupled between the electronic components 20b and 20d. Thus, the thermal dissipating structure 44b (or thermal dissipating structure 44a) may have a greater surface area exposed by the encapsulant 70 without the leakage between different power modules.

In some embodiments, the electronic device 1e may include additional heat dissipating structures (not shown). For example, the electronic device 1e may include a first additional heat dissipating structure under the substrate 10. The electronic device 1e may include a second additional heat dissipating structure over the thermal dissipating structure 44. The first and second additional heat dissipating structures may include cold plates including a liquid cooling element or other suitable structures.

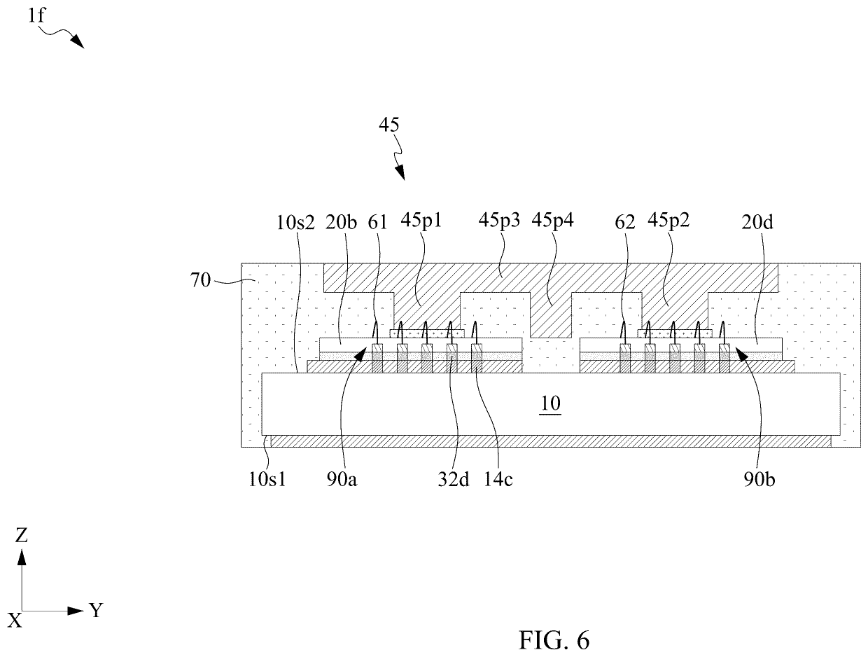

FIG. 6 illustrates a side view of an electronic device 1f in accordance with some arrangements of the present disclosure. The electronic device 1f is similar to the electronic device 1e in FIG. 5B except for the differences described as follows.

In some embodiments, the electronic device 1f may have a thermal dissipating structure 45. The thermal dissipating structure 45 may have a portion 45p1 (or a base portion) over the electronic component 20b of the power module 90a and a portion 45p2 (or a base portion) over the electronic component 20d of the power module 90b. The thermal dissipating structure 45 may have a portion 45p3 (or a connection portion) connecting the portions 45p1 and 45p2. In some embodiments, the thermal dissipating structure 45 may further include a portion 45p4 (or a protrusion) protruding toward the substrate 10. In some embodiments, the portion 45p4 may be disposed between the portions 45p1 and 45p2. In some embodiments, the portion 45p4 may laterally overlap the portion 45p1. In some embodiments, the portion 45p4 may overlap the portion 45p1 along the Y direction. The portion 45p4 may be free from vertically overlapping the electronic components 20b and 20d. The portion 45p4 may be configured to increase the surface area of the thermal dissipating structure 45, thereby enhancing the thermal transmittance.

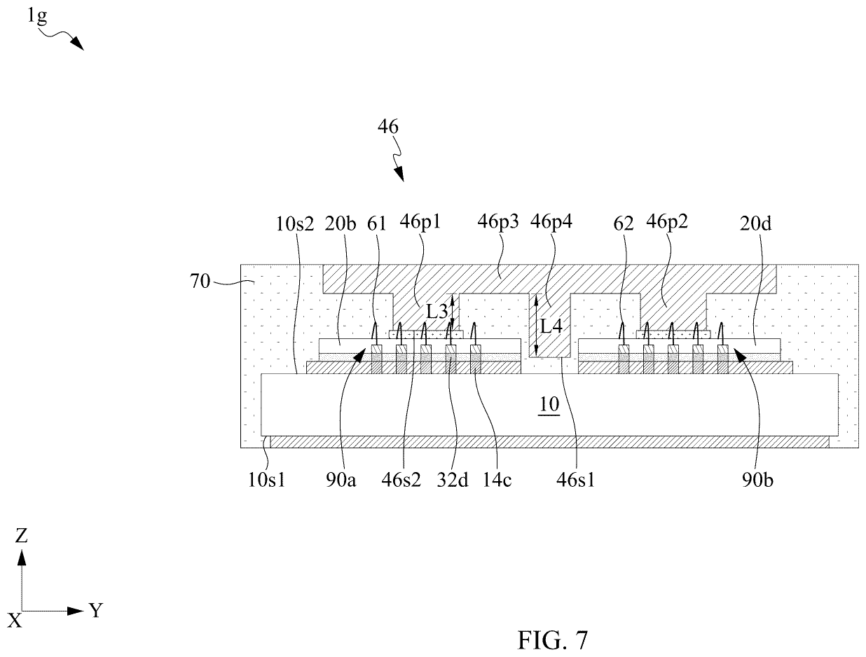

FIG. 7 illustrates a side view of an electronic device 1g in accordance with some arrangements of the present disclosure. The electronic device 1g is similar to the electronic device 1e in FIG. 5B except for the differences described as follows.

In some embodiments, the electronic device 1g may have a thermal dissipating structure 46. The thermal dissipating structure 46 may have a portion 46p1 (or a base portion) over the electronic component 20b of the power module 90a and a portion 46p2 (or a base portion) over the electronic component 20d of the power module 90b. The thermal dissipating structure 46 may have a portion 46p3 (or a connection portion) connecting the portions 46p1 and 46p2. In some embodiments, the thermal dissipating structure 46 may further include a portion 46p4 (or a protrusion) protruding toward the substrate 10. In some embodiments, the portion 46p4 may be disposed between the portions 46p1 and 46p2. In some embodiments, the portion 46p4 may laterally overlap the portion 46p1. In some embodiments, a surface 46s1 (or a lower surface) of the portion 46p4 may be located at an elevation, with respect to the surface 10s2 of the substrate 10, lower than that of a surface 46s2 (or a lower surface) of the portion 46p1. In some embodiments, the portion 46p1 may have a length L3 less than a length L4 of the portion 46p3 along the Z direction. The portion 46p4 may be configured to increase the surface area of the thermal dissipating structure 46, thereby enhancing the thermal transmittance.

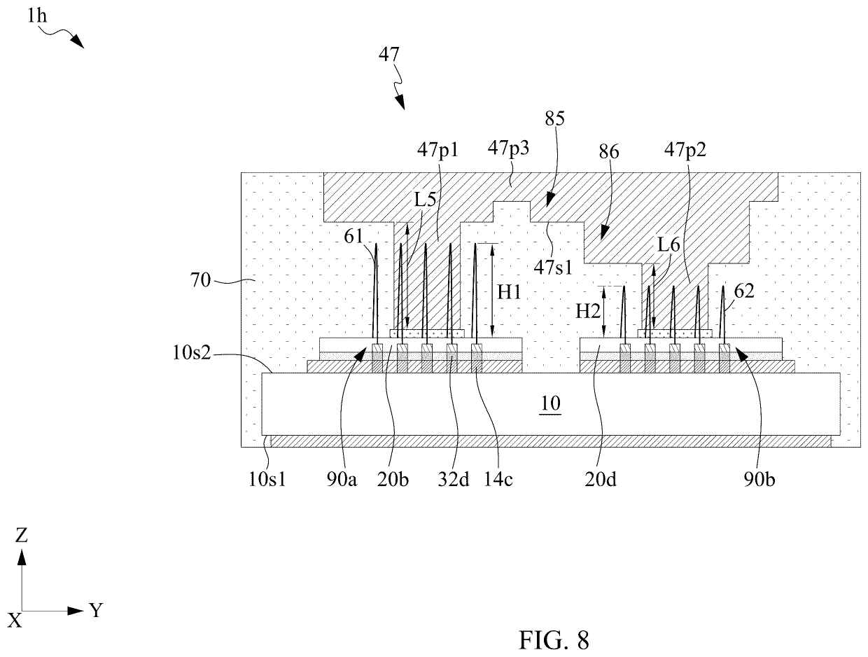

FIG. 8 illustrates a side view of an electronic device 1h in accordance with some arrangements of the present disclosure. The electronic device 1h is similar to the electronic device 1e in FIG. 5B except for the differences described as follows.

In some embodiments, the electronic device 1h may have a thermal dissipating structure 47. The thermal dissipating structure 47 may have a portion 47p1 (or a base portion) over the electronic component 20b of the power module 90a and a portion 47p2 (or a base portion) over the electronic component 20d of the power module 90b. The thermal dissipating structure 47 may have a portion 47p3 (or a connection portion) connecting the portions 47p1 and 47p2. In some embodiments, the portion 47p1 may have a length L5 greater than a length L6 of the portion 47p2 along the Z direction. In some embodiments, a surface 47s1 (or a bottom surface which includes multiple lower surfaces with different elevations) may define step structures 85 and 86. The step structures 85 and 86 may be disposed between the portions 47p1 and 47p2. The step structures 85 and 86 may be configured to accommodate the conductive wires 61 and conductive wires 62 which have different heights. For example, the conductive wires 61 may have a height H1 greater than a height H2 of the conductive wires 62. In some embodiments, the electronic component 20b, 20d, and the thermal dissipating structure 47 define spaces configured to accommodate conductive wires 61 and 62 with different heights.

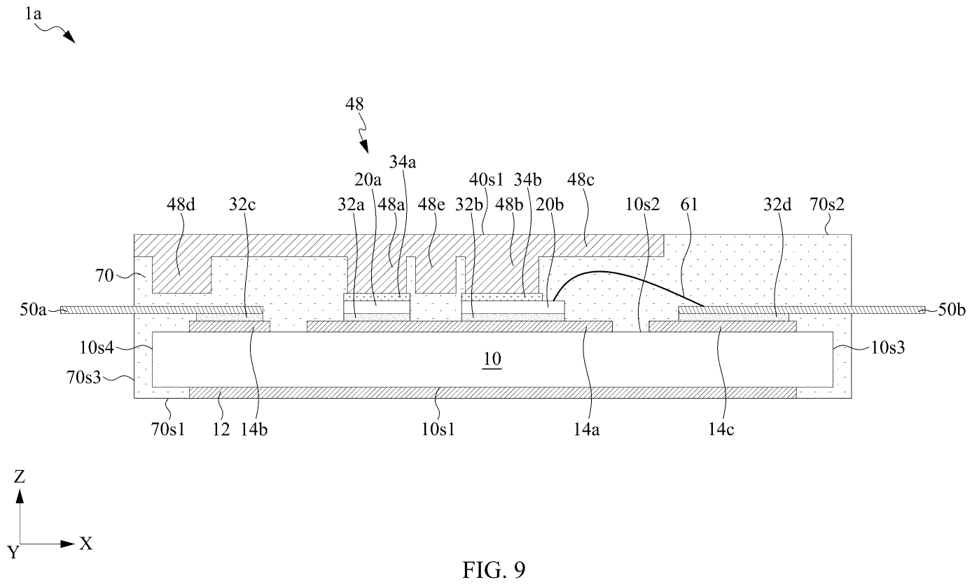

FIG. 9 illustrates a cross-sectional view of an electronic device 1i in accordance with some arrangements of the present disclosure. The electronic device 1i is similar to the electronic device 1a in FIG. 1B except for the differences described as follows.

In some embodiments, the electronic device 1h may have a thermal dissipating structure 48. In some embodiments, the thermal dissipating structure 48 may include a base portion 48a connected to the electronic component 20a, a base portion 48b connected to the electronic component 20b, and a connection portion 48c connecting the base portions 43a and 43b. In some embodiments, the connection portion 48c may be exposed by a surface 70s3 (or a lateral surface) of the encapsulant 70, thereby enhancing the thermal transmittance. In some embodiments, the thermal dissipating structure 48 may further include a protrusion 48d protruding toward the substrate 10. The protrusion 48d may be located at the same side of the base portions 48a and 48b. In some embodiments, the thermal dissipating structure 48 may further include a protrusion 48e protruding toward the substrate 10. The protrusion 48e may be disposed between the base portions 48a and 48b. The protrusions 48d and 48e may be free from vertically overlapping the dies 20a and 20b. The protrusions 48d and 48e may be configured to increase the surface area of the thermal dissipating structure 48, thereby enhancing the thermal transmittance.

As used herein, the singular terms “a,” “an,” and “the” may include a plurality of referents unless the context clearly dictates otherwise.

As used herein, the terms “conductive,” “electrically conductive” and “electrical conductivity” refer to an ability to transport an electric current. Electrically conductive materials typically indicate those materials that exhibit little or no opposition to the flow of an electric current. One measure of electrical conductivity is Siemens per meter (S/m). Typically, an electrically conductive material is one having a conductivity greater than approximately 10⁴ S/m, such as at least 10⁵ S/m or at least 10⁶ S/m. The electrical conductivity of a material can sometimes vary with temperature. Unless otherwise specified, the electrical conductivity of a material is measured at room temperature.

As used herein, the terms “approximately,” “substantially,” “substantial” and “about” are used to describe and account for small variations. When used in conjunction with an event or circumstance, the terms can refer to instances in which the event or circumstance occurs precisely as well as instances in which the event or circumstance occurs to a close approximation. For example, when used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, two numerical values can be deemed to be “substantially” the same or equal if a difference between the values is less than or equal to ±10% of an average of the values, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” parallel can refer to a range of angular variation relative to 0° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°. For example, “substantially” perpendicular can refer to a range of angular variation relative to 90° that is less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values are sometimes presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified.

While the present disclosure has been described and illustrated with reference to specific arrangements thereof, these descriptions and illustrations do not limit the present disclosure. It should be understood by those skilled in the art that various changes may be made and equivalents may be substituted without departing from the true spirit and scope of the present disclosure as defined by the appended claims. The illustrations may not be necessarily drawn to scale. There may be distinctions between the artistic renditions in the present disclosure and the actual apparatus due to manufacturing processes and tolerances. There may be other arrangements of the present disclosure which are not specifically illustrated. The specification and drawings are to be regarded as illustrative rather than restrictive. Modifications may be made to adapt a particular situation, material, composition of matter, method, or process to the objective, spirit and scope of the present disclosure. All such modifications are intended to be within the scope of the claims appended hereto. While the methods disclosed herein have been described with reference to particular operations performed in a particular order, it will be understood that these operations may be combined, sub-divided, or re-ordered to form an equivalent method without departing from the teachings of the present disclosure. Accordingly, unless specifically indicated herein, the order and grouping of the operations are not limitations of the present disclosure.

What is claimed is:

1. An electronic device, comprising:
a die;
a thermal dissipating structure disposed over the die, wherein the thermal dissipating structure has a thickness tapered along a direction far away from the die; and
an encapsulant encapsulating the die and the thermal dissipating structure.

2. The electronic device of claim 1, further comprising:
a conductive element connected to the die and spaced separated from the thermal dissipating structure.

3. The electronic device of claim 2, wherein an upper surface of the thermal dissipating structure is exposed by the encapsulant.

4. The electronic device of claim 2, wherein the thermal dissipating structure vertically overlaps the conductive element.

5. The electronic device of claim 1, wherein the thermal dissipating structure defines a first step and a second step connected to the first step.

6. The electronic device of claim 5, wherein the first step and the second step are configured to accommodate an additional element.

7. The electronic device of claim 1, wherein a lower surface of the thermal dissipating structure has a curved surface facing the die.

8. The electronic device of claim 1, further comprising:
a substrate supporting the die,
wherein the thermal dissipating structure comprises a protrusion extending toward the substrate and free from overlapping the die.

9. The electronic device of claim 8, wherein the protrusion laterally overlaps the die.

10. The electronic device of claim 8, wherein the encapsulant encapsulates a lateral surface of the substrate.

11. The electronic device of claim 1, further comprising:
a lead electrically connected to the die,
wherein the thermal dissipating structure covers the lead.

12. The electronic device of claim 1, wherein the thermal dissipating structure comprises a first base portion, a second base portion at a first side of the die, and a connection portion connecting the first base portion and the second base portion, and wherein the connection portion defines a first step and a second step at a second side, different from the first side, of the die.

13. The electronic device of claim 12, wherein the connection portion defines a first step and a second step, and an elevation of the first step is different from an elevation of the second step.

14. An electronic device, comprising:
a substrate supporting a plurality of dies; and
a thermal dissipating structure disposed over the substrate, wherein the thermal dissipating structure comprises a first base portion, a second base portion, and a connection portion connecting the first base portion and the second base portion, and wherein the connection portion exceeds a first side and a second side of the die.

15. The electronic device of claim 14, further comprising:
a bendable conductive element connected to one of the plurality of dies, wherein the connection portion vertically overlaps the bendable conductive element.

16. The electronic device of claim 15, wherein a bottom surface of the connection portion has a topography to define a space accommodating the bendable conductive element.

17. The electronic device of claim 14, wherein a vertical length of the first base portion is different from a vertical length of the second base portion.

18. An electronic device, comprising:
a substrate;
a thermal dissipating structure disposed over the substrate, wherein the thermal dissipating structure comprises a first base portion, a second base portion, and a connection portion connecting the first base portion and the second base portion, and wherein an upper surface of the connection portion continuously extends from a first side to a second side of the thermal dissipating structure and overhangs the first base portion and the second base portion.

19. The electronic device of claim 18, further comprising:
a die between the substrate and the thermal dissipating structure, wherein the die and the thermal dissipating structure define spaces configured to accommodate conductive wires with different heights.

20. The electronic device of claim 18, wherein the thermal dissipating structure has a bottom surface opposite to the upper surface, and the bottom surface has two or more elevations with respect to the substrate.
